(19) United States
(12) Patent Application Publication
(10) Pub. No.: US 2026/0223755 A1
(43) Pub. Date: Jul. 30, 2026

(54) SEMICONDUCTOR DEVICE

(71) Applicant: ROHM CO., LTD., Kyoto (JP)

(72) Inventors: Kenji FUJII, Kyoto (JP); Haruo YAMAKOSHI, Kyoto (JP)

(21) Appl. No.: 19/457,657

(22) Filed: Jan. 23, 2026

(30) Foreign Application Priority Data
Jan. 30, 2025 (JP) 2025-013888

(51) Int. Cl. H10W 90/00; H10W 70/40; H10W 72/90

(52) U.S. Cl. CPC H10W 90/738; H10W 70/421; H10W 72/944; H10W 90/756

(57) ABSTRACT

A semiconductor device includes a semiconductor element and a conductive support member. The conductive support member includes a plurality of external terminals including a first external terminal and a second external terminal. The semiconductor element includes a plurality of pads including a first pad in a conductive state with the first external terminal and a second pad in a conductive state with the second external terminal. The semiconductor device further includes a capacitor mounted on the semiconductor element in a conductive state with the first pad.

### CROSS-REFERENCE TO RELATED APPLICATION

This application is based upon and claims the benefit of priority from Japanese Patent Application No. 2025-013888, filed on Jan. 30, 2025, the entire contents of which are incorporated herein by reference.

### TECHNICAL FIELD

The present disclosure relates to a semiconductor device.

### BACKGROUND

In the related art, there is known an example of a semiconductor device. The semiconductor device in the related art includes a semiconductor element, a plurality of leads, a plurality of wires, and a sealing resin. The semiconductor element is connected to the plurality of leads via the plurality of wires. The plurality of leads is used as mounting terminals when mounting the semiconductor element on a circuit board.

### BRIEF DESCRIPTION OF DRAWINGS

The accompanying drawings, which are incorporated in and constitute a portion of the specification, illustrate embodiments of the present disclosure.

FIG. 1 is a plan view showing a semiconductor device according to a first embodiment of the present disclosure.

FIG. 2 is a bottom view showing the semiconductor device according to the first embodiment of the present disclosure.

FIG. 3 is a schematic circuit diagram showing the semiconductor device according to the first embodiment of the present disclosure.

FIG. 4 is a partially enlarged plan view showing the semiconductor device according to the first embodiment of the present disclosure.

FIG. 5 is a partially enlarged cross-sectional view taken along line V-V in FIG. 4.

FIG. 6 is a partially enlarged cross-sectional view taken along line VI-VI in FIG. 4.

FIG. 7 is a partially enlarged cross-sectional view taken along line VII-VII in FIG. 4.

FIG. 8 is a perspective view showing a capacitor of the semiconductor device according to the first embodiment of the present disclosure, as viewed from below.

FIG. 9 is a plan view showing a first modification of the semiconductor device according to the first embodiment of the present disclosure.

FIG. 10 is a plan view showing a semiconductor device according to a second embodiment of the present disclosure.

FIG. 11 is a schematic circuit diagram showing the semiconductor device according to the second embodiment of the present disclosure.

FIG. 12 is a partially enlarged plan view showing the semiconductor device according to the second embodiment of the present disclosure.

FIG. 13 is a partially enlarged cross-sectional view taken along line XIII-XIII in FIG. 12.

FIG. 14 is a plan view showing a semiconductor device according to a third embodiment of the present disclosure.

FIG. 15 is a schematic circuit diagram showing the semiconductor device according to the third embodiment of the present disclosure.

FIG. 16 is a cross-sectional view showing a semiconductor device according to a fourth embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

The terms “first,” “second,” “third,” and the like in the present disclosure are used merely to distinguish objects and are not intended to rank the objects.

In the present disclosure, unless otherwise specified, “a certain object A is formed in a certain object B” and “a certain object A is formed on a certain object B” may include “a certain object A is formed directly in a certain object B” and “a certain object A is formed in a certain object B with another object interposed between the certain object A and the certain object B.” Similarly, unless otherwise specified, “a certain object A is arranged in a certain object B” and “a certain object A is arranged on a certain object B” may include “a certain object A is arranged directly in a certain object B” and “a certain object A is arranged in a certain object B with another object interposed between the certain object A and the certain object B.” Similarly, unless otherwise specified, “a certain object A is located on a certain object B” may include “a certain object A is located on a certain object B with the certain object A in contact with the certain object B” and “a certain object A is located on a certain object B with another object interposed between the certain object A and the certain object B.” Further, unless otherwise specified, “an object A overlaps an object B when viewed in a certain direction” may include “an object A entirely overlaps an object B” and “an object A partially overlaps an object B.” In addition, in the present disclosure, “a surface A is oriented in a direction B (one side or the other side of the direction B)” is not limited to a case where an angle of a surface A with respect to a direction B is 90°, but also includes a case where a surface A is inclined with respect to a direction B.

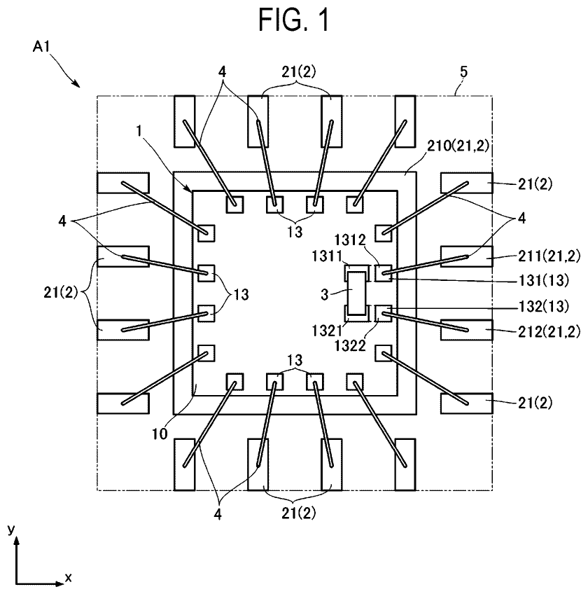

FIGS. 1 to 8 show a semiconductor device according to a first embodiment of the present disclosure. A semiconductor device A1 of this embodiment includes a semiconductor element 1, a conductive support member 2, and a capacitor 3. The semiconductor device A1 may further include a plurality of conductive connection materials 4 and a sealing resin 5. The semiconductor device A1 may have a rectangular shape with four sides extending along an x direction and a y direction in a plan view.

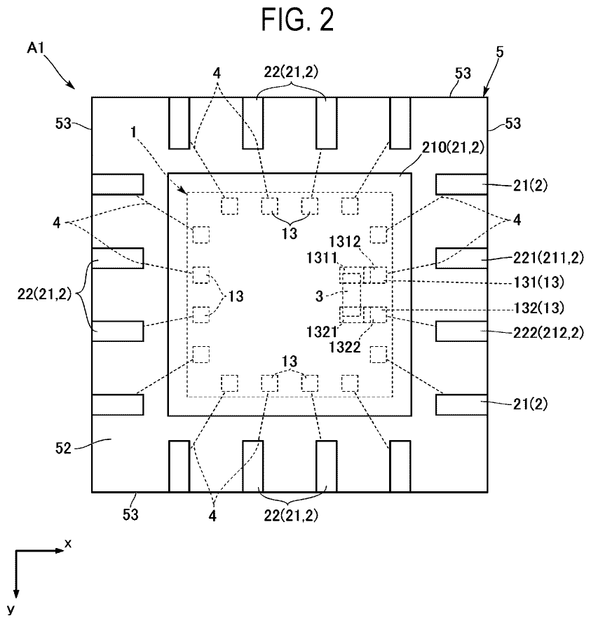

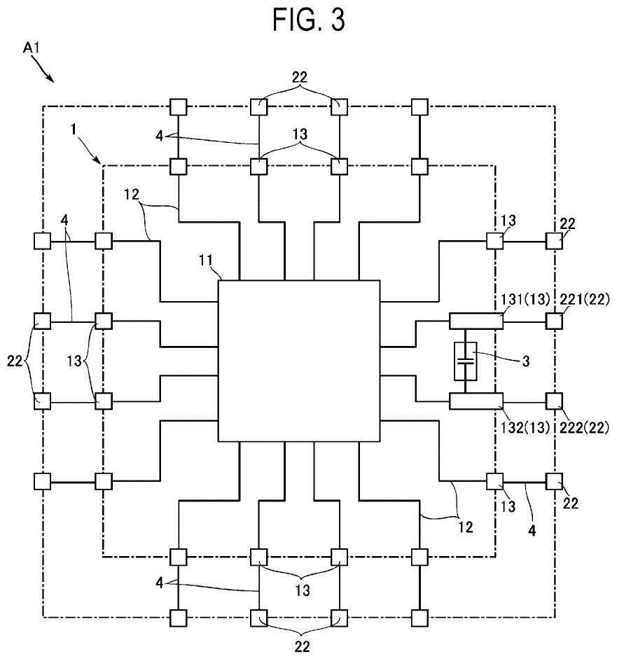

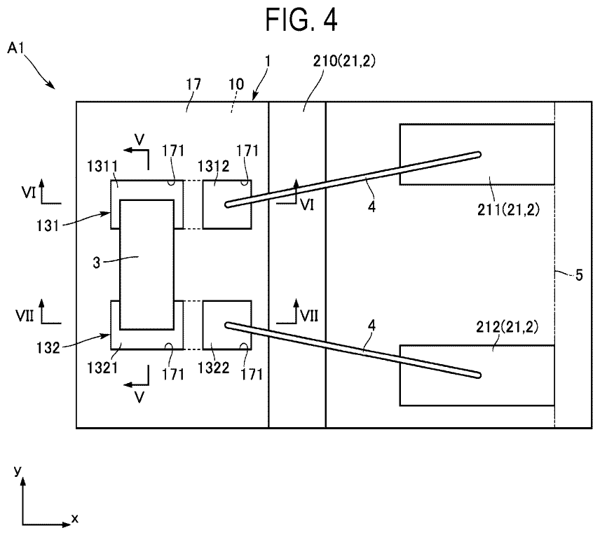

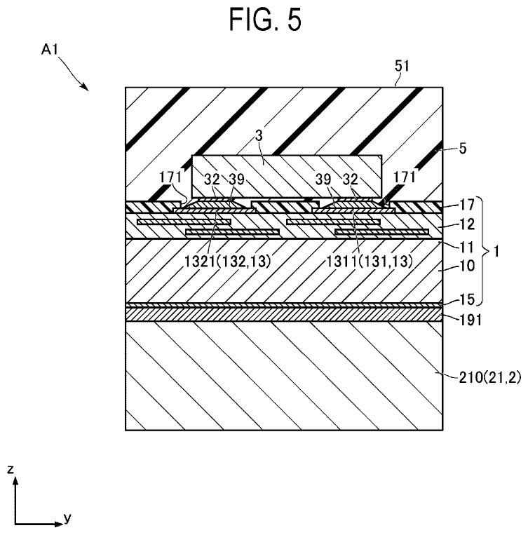

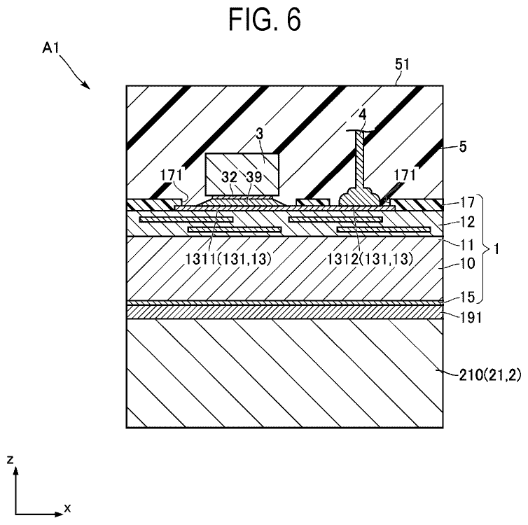

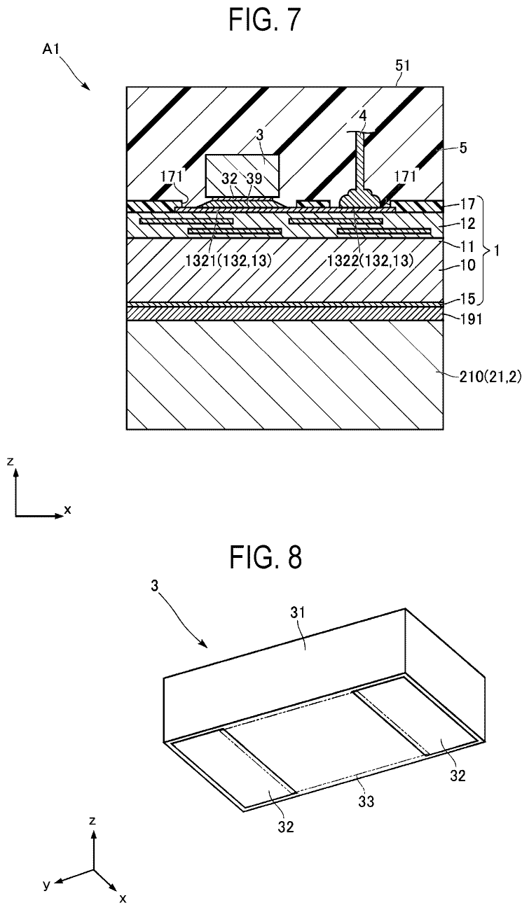

FIG. 1 is a plan view showing the semiconductor device A1. FIG. 2 is a bottom view showing the semiconductor device A1. FIG. 3 is a schematic circuit diagram showing the semiconductor device A1. FIG. 4 is a partially enlarged plan view showing the semiconductor device A1. FIG. 5 is a partially enlarged cross-sectional view taken along line V-V in FIG. 4. FIG. 6 is a partially enlarged cross-sectional view taken along line VI-VI in FIG. 4. FIG. 7 is a partially enlarged cross-sectional view taken along line VII-VII in FIG. 4. FIG. 8 is a perspective view showing the capacitor 3 of the semiconductor device A1 as viewed from below.

The semiconductor element 1 is a component that performs electrical functions of the semiconductor device A1. Specific structures and functions of the semiconductor element 1 are not particularly limited. The semiconductor element 1 may be, for example, various types of LSIs (Large Scale Integrations), ICs (Integrated Circuits), or the like. The semiconductor element 1 may be, for example, a device that inputs and outputs digital signals. The semiconductor element 1 may have a rectangular shape with four sides extending in the x and y directions in a plan view.

The semiconductor element 1 includes a plurality of pads 13. The semiconductor element 1 may further include an element body 10, a functional part 11, a rewiring layer 12, a back-surface metal layer 15, and an organic film 17.

The element body 10 occupies a majority of the semiconductor element 1 and may contain a semiconductor material. Examples of the semiconductor material may include Si, SiC, GaN, and the like The element body 10 may have a rectangular shape in a plan view.

The functional part 11 is formed in at least a portion of the element body 10. The functional part 11 may include various circuits for implementing the electrical functions to be performed by the semiconductor element 1.

For example, the rewiring layer 12 is stacked on the element body 10. The rewiring layer 12 is constituted with one or more conductor layers containing a metal such as aluminum. The one or more conductor layers may be arranged alternately with a plurality of insulating layers.

The plurality of pads 13 are portions for electrically connecting the semiconductor element 1. In this embodiment, the plurality of pads 13 are connected to the functional part 11 via the rewiring layer 12. That is, the rewiring layer 12 constitutes a plurality of conductive paths which connect the functional part 11 and the pads 13. The plurality of pads 13 include a first pad 131 and a second pad 132. Each of the plurality of pads 13 may have a single-layer of metal layer or a multi-layer of metal layers, containing a metal such as Cu (copper), Ni (nickel), Pd (palladium), or Au (gold). The plurality of pads 13 may be aligned in the x and y directions along the four sides of the element body 10.

The back-surface metal layer 15 is provided on one surface of the element body 10 in a z direction. The back-surface metal layer 15 may be composed of, for example, a metal such as Al (aluminum), Ni (nickel), Cu (copper), Ag (silver), or an alloy thereof.

The conductive support member 2 supports the semiconductor element 1 and constitutes a conductive path between the semiconductor element 1 and the outside. A specific configuration of the conductive support member 2 is not particularly limited. Examples of the conductive support member 2 may include one constituted with a plurality of leads and one constituted with a wiring board. In this embodiment, the conductive support member 2 is constituted with a plurality of leads 21. The plurality of leads 21 may be arranged in the x direction and the y direction.

Each of the plurality of leads 21 may be composed of a metal such as Cu (copper), Ni (nickel), or Fe (iron), or an alloy thereof. A plating layer composed of a metal such as Ni (nickel), Pd (palladium), Ag (silver), or Sn (tin) may be formed in appropriate locations on each of the plurality of leads 21. Some of the plurality of leads 21, which are exposed from the sealing resin 5, are used as a plurality of external terminals 22 for mounting the semiconductor device A1 on a circuit board or the like.

The plurality of leads 21 may include an island lead 210. The capacitor 3 is mounted on the island lead 210. In this example, the back-surface metal layer 15 of the semiconductor element 1 is bonded to the island lead 210 by a bonding material 191. The other leads 21 are arranged so as to surround the island lead 210.

The plurality of conductive connection materials 4 are provided to render the semiconductor element 1 and the conductive support member 2 electrically conductive. A specific configuration of each of the plurality of conductive connection materials 4 is not particularly limited. Each of the plurality of conductive connection materials 4 may be, for example, a wire containing a metal, a conductive member made of a metal plate material, or the like. In this embodiment, each of the plurality of conductive connection materials 4 is a wire. The plurality of pads 13 and the plurality of external terminals 22 corresponding thereto are in a conductive state with each other via the plurality of conductive connection materials 4. The first pad 131 is in a conductive state with a first external terminal 221, and the second pad 132 is in a conductive state with a second external terminal 222.

The capacitor 3 is a passive element for reducing ringing in the semiconductor device A1. The capacitor 3 is mounted on the semiconductor element 1. The capacitor 3 is in a conductive state with the first pad 131 and eventually with the first external terminal 221. In this embodiment, the capacitor 3 may be in a conductive state with the second pad 132 and eventually with the second external terminal 222.

A specific configuration of the capacitor 3 is not particularly limited. Examples of the capacitor 3 may include a ceramic capacitor, a tantalum capacitor, a silicon capacitor, and the like. In this embodiment, the capacitor 3 is the silicon capacitor and may include a capacitor body portion 31, a plurality of capacitor electrodes 32, and a capacitance portion 33. In a plan view, the capacitor 3 may entirely overlap the semiconductor element 1.

The capacitor body portion 31 constitutes a majority of the capacitor 3 and is a base material for forming the capacitance portion 33. The capacitor body portion 31 includes a semiconductor such as Si. The plurality of capacitor electrodes 32 are portions used for mounting the capacitor 3. The plurality of capacitor electrodes 32 are located to be spaced apart from one another on, for example, one side of the capacitor body portion 31. Each of the plurality of capacitor electrodes 32 is configured as a conductor layer composed of, for example, a metal or an alloy.

The capacitance portion 33 is formed on one side of the capacitor body portion 31 and constitutes an electrical capacitance of the capacitor 3. The capacitance portion 33 is electrically provided between two capacitor electrodes 32. A specific configuration of the capacitance portion 33 is not particularly limited, and may be of, for example, a planar type, a trench type, or the like. The planar type of capacitance portion 33 includes a dielectric layer expanding along one side of the capacitor body portion 31 and two electrode layers. The two electrode layers are stacked one on the other via the dielectric layer. The trench type of capacitance portion 33 includes multiple fine recesses (trench structures) in the capacitor body portion 31. The dielectric layer and the two electrode layers are three-dimensionally formed along the multiple fine recesses (trenches). In this embodiment, the capacitor 3 is of, for example, the trench type, which is advantageous in reducing the size and increasing the capacitance.

As shown in FIGS. 4 to 7, one of the two capacitor electrodes 32 is conductively bonded to the first pad 131 by a conductive connection material 39, and the other of the two capacitor electrodes 32 is conductively bonded to the second pad 132 by the conductive connection material 39. An example of the conductive connection material 39 may include solder, Ag paste, or the like.

In this example, the semiconductor element 1 may include the organic film 17. The organic film 17 is provided on one side of the element body 10 to appropriately cover the functional part 11, the rewiring layer 12, the plurality of pads 13, and the like The organic film 17 may be, for example, a polymer film or a synthetic film, and may contain cellulose acetate, polysulfone, polyethylene, polypropylene, polyacrylonitrile, or the like

The organic film 17 may have a plurality of openings 171. The organic film 17 exposes, for example, appropriate locations of the plurality of pads 13. The first pad 131 may include a first exposed portion 1311 and a third exposed portion 1312 which are individually exposed through the two openings 171. The second pad 132 may include a second exposed portion 1321 and a fourth exposed portion 1322 which are individually exposed through the two openings 171.

In the capacitor 3, one capacitor electrode 32 is conductively bonded to the first exposed portion 1311, and the other capacitor electrode 32 is conductively bonded to the second exposed portion 1321. The third exposed portion 1312 is connected to the first lead 211 via the conductive connection material 4, and is in a conductive state with the first external terminal 221. The fourth exposed portion 1322 is connected to the second lead 212 via the conductive connection material 4, and is in a conductive state with the second external terminal 222.

In this example, the first exposed portion 1311 and the second exposed portion 1321 are respectively located inward of the third exposed portion 1312 and the fourth exposed portion 1322 in a plan view (on the left side in the x direction in FIG. 4). As a result, the capacitor 3 is located inward of the third exposed portion 1312 and the fourth exposed portion 1322 in a plan view. The first exposed portion 1311 and the second exposed portion 1321 are arranged side by side in the y direction. The third exposed portion 1312 and the fourth exposed portion 1322 are arranged side by side in the y direction.

The sealing resin 5 covers the semiconductor element 1, the capacitor 3, the plurality of conductive connection materials 4, and a portion of the conductive support member 2. The sealing resin 5 contains an insulating resin material such as an epoxy resin.

The sealing resin 5 may have, for example, a resin main surface 51, a resin rear surface 52, and a plurality of resin side surfaces 53. The resin main surface 51 is oriented to one side in the z direction. The resin rear surface 52 is oriented to the other side in the z direction. The plurality of resin side surfaces 53 are connected to the resin main surface 51 and the resin rear surface 52 and are oriented in the x direction or the y direction. In this example, the plurality of leads 21 are exposed from the resin rear surface 52. Further, the plurality of leads 21 excluding the island lead 210 may be exposed from the plurality of resin side surfaces 53 in the x direction or the y direction.

Next, an operation of the semiconductor device A1 will be described.

The semiconductor device A1 further includes the capacitor 3 mounted on the semiconductor element 1 and in a conductive state with the first pad 131. For example, compared to a configuration in which the capacitor 3 is mounted on a circuit board on which the semiconductor device A1 is mounted, or a configuration in which the capacitor 3 is connected to the first lead 211, the semiconductor device A1 has a relatively short path length between the capacitor 3 and the functional part 11. This makes it possible to reduce ringing in the conductive path that includes a portion extending from the functional part 11 to the first external terminal 221 via the first pad 131.

Further, the capacitor 3 is in a conductive state with the second pad 132 and the second external terminal 222. Thus, the capacitor 3 is connected to a portion extending from the functional part 11 to the first external terminal 221 via the first pad 131, and to a portion extending from the functional part 11 to the second external terminal 222 via the second pad 132. This makes it possible to more effectively reduce the ringing.

The capacitor 3 is conductively bonded to the first exposed portion 1311 and the second exposed portion 1321 by the conductive connection material 39. The first exposed portion 1311 is separated from the third exposed portion 1312 by the organic film 17, and the second exposed portion 1321 is separated from the fourth exposed portion 1322 by the organic film 17. This makes it possible to prevent the conductive connection material 39 from spreading from the first exposed portion 1311 and the second exposed portion 1321 to the third exposed portion 1312 and the fourth exposed portion 1322. Accordingly, it is possible to suppress defective connection of the conductive connection material 4.

The first exposed portion 1311 and the second exposed portion 1321 are respectively located inward of the third exposed portion 1312 and the fourth exposed portion 1322 in a plan view. This makes it possible to further shorten the conductive path between the functional part 11 and the capacitor 3. Accordingly, it is possible to further reduce the ringing.

The capacitor 3 is a silicon capacitor, and the capacitance portion 33 has a trench structure. Therefore, the capacitor 3 may be reduced in size, and may be appropriately mounted on the semiconductor element 1. In the semiconductor device A1, the reduction in size of the capacitor 3 makes it possible to implement a configuration in which the capacitor 3 does not protrude from the semiconductor element 1.

Further, the capacitor body portion 31 of the capacitor 3 contains a semiconductor such as Si, just like the element body 10 of the semiconductor element 1. Therefore, a linear expansion coefficient of the capacitor body portion 31 may be brought closer to that of the element body 10, thereby reducing thermal stress generated in the capacitor 3 and the semiconductor element 1, or in the conductive connection material 39, during the operation of the semiconductor device A1.

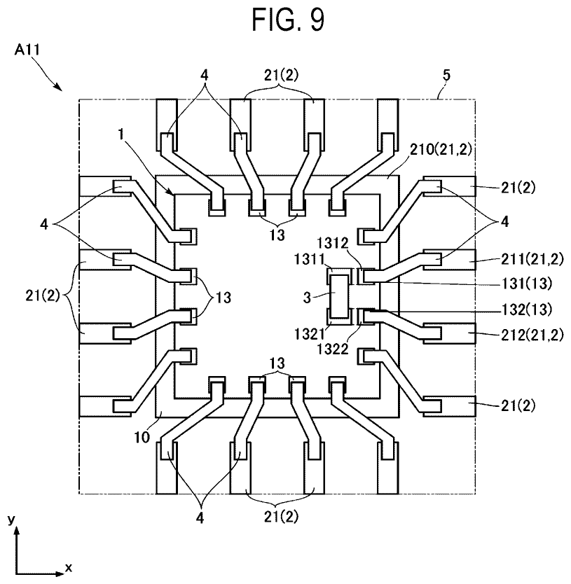

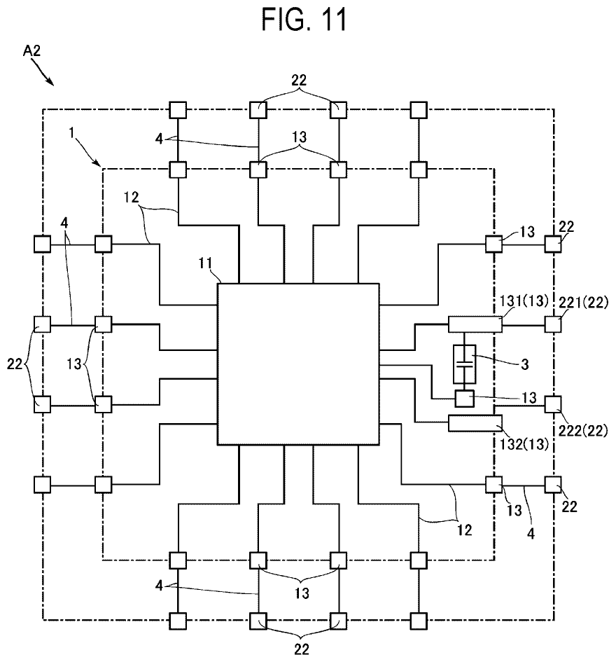

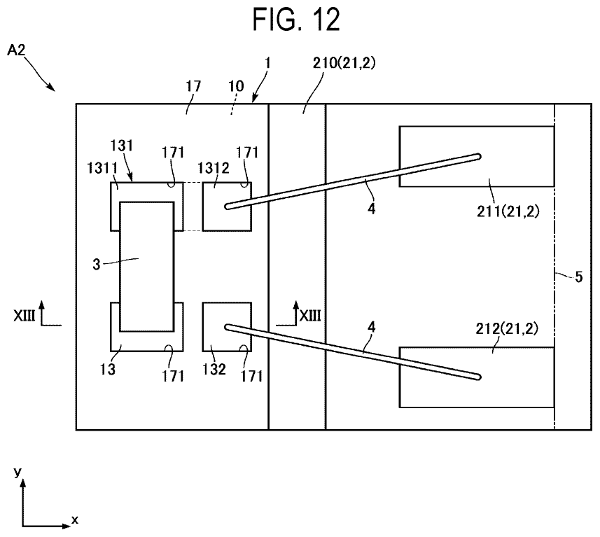

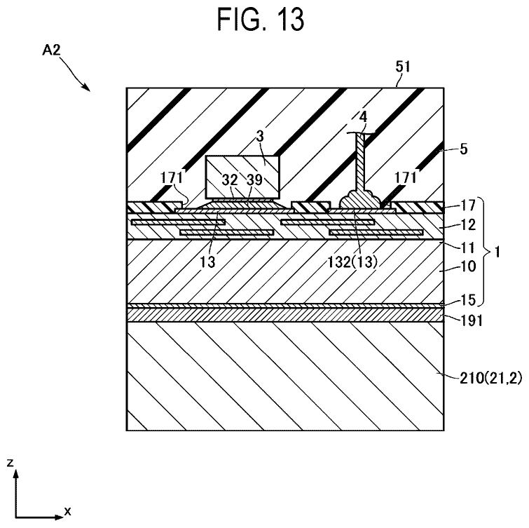

FIGS. 9 to 16 show modifications and other embodiments of the present disclosure. In these figures, elements that are the same as or similar to those in the above-described embodiment are designated by the same reference numerals. Further, the configurations of the various parts in the respective modifications and the respective embodiments may be combined with each other as appropriate within the scope that does not cause technical contradictions.

FIG. 9 shows a first modification of the semiconductor device A1. In a semiconductor device A11 of the first modification, the plurality of conductive connection materials 4 are composed of conductive members made of a metal plate material.

Even in the first modification, it is possible to reduce ringing in the semiconductor device A11. Further, as can be seen from this modification, the configuration of the plurality of conductive connection materials 4 is not particularly limited.

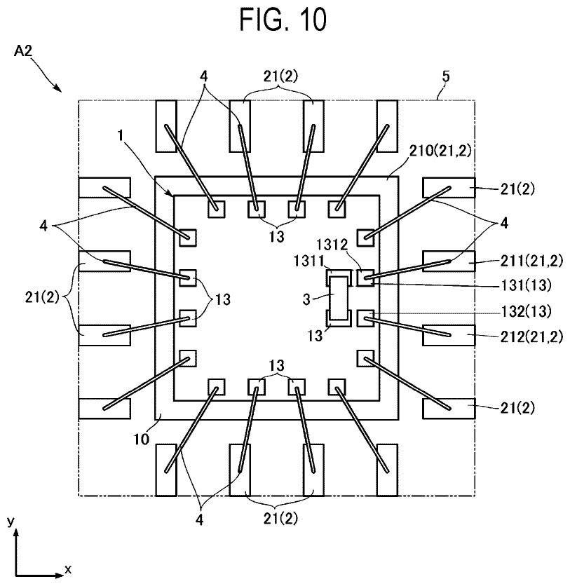

FIGS. 10 to 13 show a semiconductor device according to a second embodiment of the present disclosure. In a semiconductor device A2 according to this embodiment, the capacitor 3 is in a conductive state with the first pad 131 and is not connected to the second pad 132, so that the capacitor 3 is insulated from the second external terminal 222.

One capacitor electrode 32 is conductively bonded to the first exposed portion 1311 by the conductive connection material 39. The other capacitor electrode 32 is conductively bonded to the pad 13 other than the first pad 131 and the second pad 132 by the conductive connection material 39. The pad 13 to which the capacitor 3 is conductively bonded is located inward of the second pad 132 in a plan view.

According to this embodiment, it is possible to reduce ringing in the semiconductor device A2. Further, as can be understood from this embodiment, the capacitor 3 is not limited to a configuration in which the capacitor 3 is in a conductive state with both the first external terminal 221 and the second external terminal 222 via the first pad 131 and the second pad 132. The capacitor 3 may be in a conductive state with the first pad 131 and may be in a non-conductive state with the second pad 132.

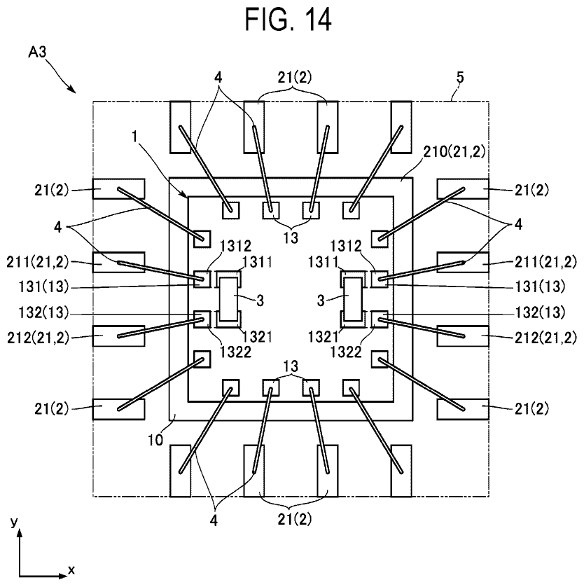

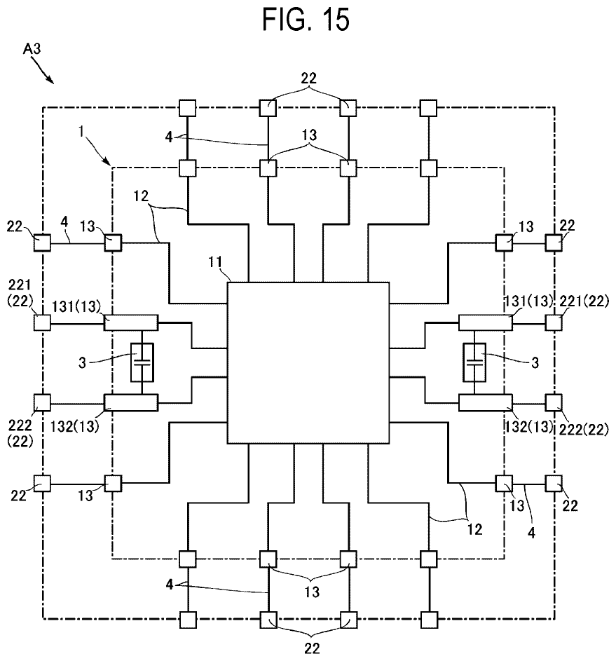

FIGS. 14 and 15 show a semiconductor device according to a third embodiment of the present disclosure. A semiconductor device A3 of this embodiment includes two capacitors 3, and two first pads 131, two second pads 132, two first leads 211, and two second leads 212. Connection relationships between the respective capacitors 3 and the respective first pads 131, the respective second pads 132, the respective first leads 211, and the respective second leads 212 may be the same as, for example, the connection relationships in the semiconductor device A1.

According to this embodiment, it is possible to reduce ringing in the semiconductor device A3. Further, as can be understood from this embodiment, the number of capacitors 3 is not particularly limited, and may be one or more.

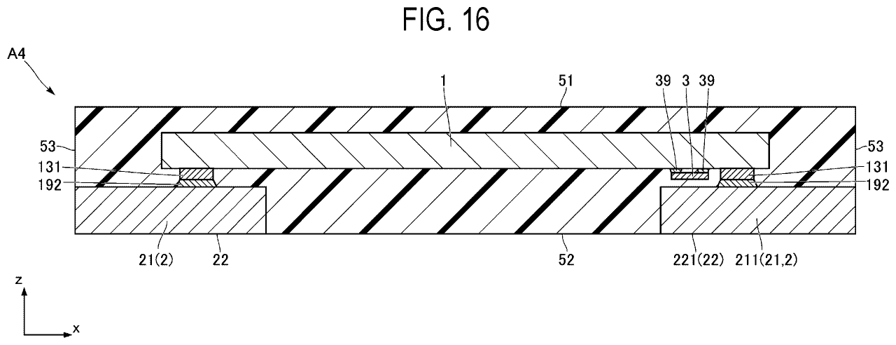

FIG. 16 shows a semiconductor device according to a fourth embodiment of the present disclosure. In a semiconductor device A4 of this embodiment, a semiconductor element 1 is mounted on a conductive support member 2 by so-called flip-chip mounting.

The plurality of pads 13 are individually bonded conductively to the plurality of leads 21 via conductive connection materials 192. The conductive connection material 192 may be, for example, solder, Ag paste, and the like. Conductive connection relationships between the capacitor 3, the first pad 131, the second pad 132, the first lead 211, and the second lead 212 may be the same as, for example, those in the semiconductor device A1.

According to this embodiment, it is possible to reduce ringing in the semiconductor device A3. Further, as can be understood from this embodiment, the mounting form of the semiconductor element 1 is not particularly limited. For example, the semiconductor element 1 may be accommodated inside the conductive support member 2.

The semiconductor device according to the present disclosure is not limited to the above-described embodiments, and the specific configuration of each part of the semiconductor device according to the present disclosure may be changed in various forms.

The present disclosure includes embodiments set forth in the following supplementary notes.

### Supplementary Note 1

A semiconductor device (A1) includes:
a semiconductor element (1); and
a conductive support member (2),
wherein the conductive support member (2) includes a plurality of external terminals (22) including a first external terminal (221) and a second external terminal (222),
the semiconductor element (1) includes a plurality of pads (13) including a first pad (131) in a conductive state with the first external terminal (221) and a second pad (132) in a conductive state with the second external terminal (222), and
the semiconductor device (A1) further includes a capacitor (3) mounted on the semiconductor element (1) and in a conductive state with the first pad (131).

### Supplementary Note 2

In the semiconductor device (A1) of Supplementary Note 1 above, the capacitor (3) is conductively bonded to the first pad (131) by a conductive connection material (39).

### Supplementary Note 3

In the semiconductor device (A1) of Supplementary Note 1 or 2 above, the capacitor (3) is further in a conductive state with the second pad (132).

### Supplementary Note 4

In the semiconductor device (A1) of Supplementary Note 3 above, the capacitor (3) is conductively bonded to the second pad (132) by the conductive connection material (39).

### Supplementary Note 5

In the semiconductor device (A1) of Supplementary Note 3 or 4 above, the semiconductor element (1) includes an organic film (17) covering at least a portion of the first pad (131) and having a plurality of openings (171).

### Supplementary Note 6

In the semiconductor device (A1) of Supplementary Note 5 above, the first pad (131) includes a first exposed portion (1311) exposed through a first opening of the plurality of openings (171), and
the capacitor (3) is conductively bonded to the first exposed portion (1311).

### Supplementary Note 7

In the semiconductor device (A1) of Supplementary Note 6 above, the second pad (132) includes a second exposed portion (1321) exposed through a second opening of the plurality of openings (171), and
the capacitor (3) is conductively bonded to the second exposed portion (1321).

### Supplementary Note 8

In the semiconductor device (A1) of Supplementary Note 7 above, the first pad (131) includes a third exposed portion (1312) exposed from a third opening of the plurality of openings (171), and
the semiconductor device (A1) further includes a first conductive connection material (41) connected to the third exposed portion (1312) and in a conductive state with the first external terminal (221).

### Supplementary Note 8-1

In the semiconductor device (A1) of Supplementary Note 8 above, the capacitor (3) is located inward of the third exposed portion (1312) in a plan view.

### Supplementary Note 9

In the semiconductor device (A1) of Supplementary Note 8 above, the second pad (132) includes a fourth exposed portion (1322) exposed from a fourth opening of the plurality of openings (171), and
the semiconductor device (A1) further includes a second conductive connection material (42) connected to the fourth exposed portion (1322) and in a conductive state with the second external terminal (222).

### Supplementary Note 9-1

In the semiconductor device (A1) of Supplementary Note 9 above, the capacitor (3) is located inward of the fourth exposed portion (1322) in a plan view.

### Supplementary Note 10

In the semiconductor device (A1) of any one of Supplementary Notes 1 to 9 above, the conductive support member (2) includes a plurality of leads (21) including a first lead (211) having the first external terminal (221) and a second lead (212) having the second external terminal (222).

### Supplementary Note 11

In the semiconductor device (A1) of any one of Supplementary Notes 1 to 10 above, the capacitor (3) includes a capacitor body portion (31) containing a semiconductor and two capacitor electrodes (32), and
the capacitor body portion (31) includes a capacitance portion (33) electrically interposed between the two capacitor electrodes (32).

### Supplementary Note 12

In the semiconductor device (A1) of Supplementary Note 11 above, the capacitor body portion (31) contains Si.

### Supplementary Note 12-1

In the semiconductor device (A1) of Supplementary Note 12 above, the capacitance portion (33) has a trench structure.

### Supplementary Note 13

In the semiconductor device (A2) of Supplementary Note 1 above, the capacitor (3) is insulated from the second external terminal (222).

### [Supplementary Note 14] (Flip Chip)

In the semiconductor device (A3) of Supplementary Note 10 above, the first pad (131) is conductively bonded to each of the plurality of leads (21) by a conductive connection material (192), and
the second pad (132) is conductively bonded to the external terminal (22) by the conductive connection material (192).

### Supplementary Note 15

In the semiconductor device (A1) of Supplementary Note 9 above, the first conductive connection material (41) and the second conductive connection material (42) are wires.

### Supplementary Note 16

In the semiconductor device (A1) of Supplementary Note 9 above, the first conductive connection material (41) and the second conductive connection material (42) are metal plate members.

### Supplementary Note 17

In the semiconductor device (A1) of any one of Supplementary Notes 1 to 16 above, the first pad (131) contains Cu.

### Supplementary Note 18

In the semiconductor device (A1) of any one of Supplementary Notes 1 to 17above, the capacitor (3) entirely overlaps the semiconductor element (1) in a plan view.

While certain embodiments have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a semiconductor element; and
a conductive support member,
wherein the conductive support member includes a plurality of external terminals including a first external terminal and a second external terminal,
wherein the semiconductor element includes a plurality of pads including a first pad in a conductive state with the first external terminal and a second pad in a conductive state with the second external terminal, and
wherein the semiconductor device further comprises a capacitor mounted on the semiconductor element in a conductive state with the first pad.

2. The semiconductor device of claim 1, wherein the capacitor is conductively bonded to the first pad by a conductive connection material.

3. The semiconductor device of claim 1, wherein the capacitor is further in a conductive state with the second pad.

4. The semiconductor device of claim 3, wherein the capacitor is conductively bonded to the second pad by a conductive connection material.

5. The semiconductor device of claim 3, wherein the semiconductor element includes an organic film covering at least a portion of the first pad and having a plurality of openings.

6. The semiconductor device of claim 5, wherein the first pad includes a first exposed portion exposed through a first opening of the plurality of openings, and
wherein the capacitor is conductively bonded to the first exposed portion.

7. The semiconductor device of claim 6, wherein the second pad includes a second exposed portion exposed through a second opening of the plurality of openings, and
wherein the capacitor is conductively bonded to the second exposed portion.

8. The semiconductor device of claim 7, wherein the first pad includes a third exposed portion exposed from a third opening of the plurality of openings, and
wherein the semiconductor device further comprises a first conductive connection material connected to the third exposed portion and in a conductive state with the first external terminal.

9. The semiconductor device of claim 8, wherein the second pad includes a fourth exposed portion exposed from a fourth opening of the plurality of openings, and
wherein the semiconductor device further comprises a second conductive connection material connected to the fourth exposed portion and in a conductive state with the second external terminal.

10. The semiconductor device of claim 1, wherein the conductive support member includes a plurality of leads including a first lead having the first external terminal and a second lead having the second external terminal.

11. The semiconductor device of claim 1, wherein the capacitor includes a capacitor body portion provided with a semiconductor and two capacitor electrodes, and
wherein the capacitor body portion includes a capacitance portion electrically interposed between the two capacitor electrodes.

12. The semiconductor device of claim 11, wherein the capacitor body portion contains Si.

13. The semiconductor device of claim 1, wherein the capacitor is insulated from the second external terminal.

14. The semiconductor device of claim 10, wherein the first pad is conductively bonded to each of the plurality of leads by a conductive connection material, and
wherein the second pad is conductively bonded to the second external terminal by the conductive connection material.

15. The semiconductor device of claim 9, wherein the first conductive connection material and the second conductive connection material are wires.
